(19) United States
(12) Patent Application Publication
(10) Pub. No.: US 2021/0405478 A1
(43) Pub. Date: Dec. 30, 2021

(54) ARRAY SUBSTRATE AND MANUFACTURING METHOD THEREOF, AND DISPLAY PANEL

(71) Applicant: TCL CHINA STAR OPTOELECTRONICS TECHNOLOGY CO., LTD., Shenzhen, Guangdong (CN)

(72) Inventor: Qingyong ZHU, Shenzhen, Guangdong (CN)

(21) Appl. No.: 16/641,043

(22) PCT Filed: Jan. 6, 2020
(86) PCT No.: PCT/CN2020/070407

§ 371 Date: Feb. 21, 2020

(30) Foreign Application Priority Data
Dec. 25, 2019 (CN) 201911357066.5

(51) Int. Cl. G02F 1/1362; H01L 27/12; G02F 1/1345; G02F 1/1333; G02F 1/1335

(52) U.S. Cl. CPC G02F 1/136231; H01L 27/124; H01L 27/1288; G02F 2202/28; G02F 1/133388; G02F 1/133514; G02F 1/136286; G02F 1/13454

(57) ABSTRACT

An array substrate and a method of manufacturing the same, and a display panel are disclosed. The array substrate includes a substrate, a first metal layer, a first insulating layer, an electrically conductive layer, and a second metal layer. The first metal layer and the second metal layer are electrically connected through a through hole on the first insulating layer and a second conductive portion of the electrically conductive layer, so that a contact resistance between the first. metal layer and the second metal layer can be reduced, a problem of gradient lines likely to occur in a display panel can be overcome, and display quality of the display panel can be improved.

### BACKGROUND OF INVENTION

### 1. Field of Invention

The present invention relates to a technical field of displays, and particularly to, an array substrate and a manufacturing method thereof, and a display panel.

### 2. Related Art

During preparation of display panels, second metal layers, protection layers, and pixel electrode layers of array substrates are fabricated by a total of three exposure masks, through three exposure and development processes, making the production process complicated and expensive. In addition, in order to achieve narrow bezel design, display panels generally use a structure in which gate driver on array (GOA) structures are fabricated on array substrates, and therefore GOA circuitry is formed on the array substrates. Please refer to FIG. 1 showing a schematic structural view of gate driver on array circuitry of a conventional display panel. A first metal layer 101 and a second metal layer 102 are surface-bonded by a conductive layer 103. Specifically, the conductive layer 103 realizes electrical connection between the first metal layer 101 and the second metal layer 102 through via holes on a gate insulating layer 104 and via holes on a protection layer 105. There will be a large transfer contact resistance between the first metal layer 101 and the second metal layer 102, and the conductive layer 103 is susceptible to corrosion under a. negative voltage, resulting in poor connection between the first metal layer 101 and the second metal layer 102, causing problems such as gradient lines and abnormal display of the display panel.

SUMMARY OF INVENTION

The present application provides an array substrate and a manufacturing method thereof, and a display panel capable of reducing a contact resistance of a gate electrode, overcoming the problem that gradient lines are likely to occur when a display panel is displaying images, improving display quality, and reducing a number of masks used for manufacturing the array substrate.

An embodiment of the present application provides an array substrate, comprising a substrate comprising a first area, a second area, and a third area, wherein the second area is disposed between the first area. and the third area; a first metal layer comprising a first metal component disposed in the first area on the substrate and a second metal component disposed in the third area on the substrate; a first insulating layer covering the first metal layer and the substrate, wherein the first insulating layer is provided with a through hole corresponding to a position of the third area; an electrically conductive layer disposed on a side of the first insulating layer away from the first metal layer and comprising a plurality of first conductive portions disposed in the first area and the second. area, a second conductive portion disposed in the third area, and at least part of the second conductive portion connected to the second metal component through the through hole; and a second metal layer comprising a third metal component disposed in the first area on the substrate and a fourth metal component disposed in the third area on the substrate, wherein the fourth metal component is connected to the second conductive portion.

In the array substrate, the array substrate comprises a display area and a non-display area, wherein the non-display area comprises a gate driver circuit area, and the gate driver circuit area comprises a first trace and a second trace; wherein the first area and the second area of the substrate are located corresponding to the display area of the array substrate; the third area of the substrate is located corresponding to the gate driver circuit area of the non-display area of the array substrate; and the second metal component is defined as the first trace of the gate driver circuit area, and the fourth metal component is defined as the second trace of the gate driver circuit area.

In the array substrate, the first metal component is defined as a gate electrode and a scan line.

In the array substrate, the third metal component is defined as a source electrode and a drain electrode.

In the array substrate, the array substrate further comprises a protection layer, and the protection layer covers the electrically conductive layer and the second metal layer.

In the array substrate, the array substrate further comprising a semiconductor layer disposed corresponding to the first area of the substrate and located between the first insulating layer and the electrically conductor layer.

An embodiment of the present application further provides a method of manufacturing an array substrate, comprising the following steps S10: providing a substrate comprising a first area, a second area, and a third area, wherein the second area is disposed between the first area and the third area; S20: forming an entire first metal layer on a surface of the substrate, and patterning the first metal layer, wherein the patterned first metal layer comprises a first metal component disposed in the first area on the substrate and a second metal component disposed in the third area on the substrate; S30: forming a first insulating layer covering the first metal layer and the substrate, wherein the first insulating layer is provided with a through hole corresponding to a position of the third area; S40: forming a semiconductor layer on a surface of the first insulating layer in the first area away from the substrate; S50: sequentially forming an entire electrically conductive layer and an entire second metal layer both covering the first insulating layer and the semiconductor layer; and S60: providing a mask, and exposing the electrically conductive layer and the second metal layer using the mask, along with subsequent development and etching processes, to enable the electrically conductive layer to form a plurality of first conductive portions in the first area and the second area and a second conductive portion in the third area, wherein the second metal layer forms a third metal component in the first area and a fourth metal component in the third area.

In the method of manufacturing the array substrate, the mask comprises a full exposure area, a half exposure area, and a reserved area, wherein the step S60 further comprises S601: preparing a photoresist layer on a surface of the second metal layer; S602: exposing the photoresist layer using the mask, wherein a first photoresist area is formed on the photoresist layer corresponding to the full exposure area of the mask, a second photoresist area is formed on the photoresist layer corresponding to the half exposure area of the mask, and a third photoresist area is formed on the photoresist layer corresponding to the reserved area of the mask; S603: removing the photoresist layer, the second metal layer, and the electrically conductive layer in the first photoresist area, so that the semiconductor layer is exposed to the first area of the substrate, and exposing part of the first insulating layer to the second area and the third area of the substrate, so that the electrically conductive layer is patterned; S604: removing the photoresist layer and the second metal layer in the second photoresist area, so that the electrically conductive layer is exposed to the first area and the second area of the substrate, and the plurality of first conductive portions are formed; and S605: removing the photoresist layer in the third photoresist area, so that the second metal layer is exposed to the first area of the substrate and the third metal component is formed, and exposing the second metal layer to the third area of the substrate, so that the fourth metal component is formed.

In the method of manufacturing the array substrate, after the step S60, the manufacturing method further comprises S70: fabricating a protection layer for covering the electrically conductive layer and the second metal layer.

An embodiment of the present application further provides a display panel, comprising the array substrate of claim 1, wherein the array substrate comprises a substrate comprising a first area, a second area, and a third area, wherein the second area is disposed between the first area and the third area; a first metal layer comprising a first metal component disposed in the first area on the substrate and a second metal component disposed in the third area on the substrate; a first insulating layer covering the first metal layer and the substrate, wherein the first insulating layer is provided with a through hole corresponding to a position of the third area; an electrically conductive layer disposed on a side of the first insulating layer away from the first metal layer and comprising a plurality of first conductive portions disposed in the first area and the second area, a second conductive portion disposed in the third area, and at least part of the second conductive portion connected to the second metal component through the through hole; and a second metal layer comprising a third metal component disposed in the first area on the substrate and a fourth metal component disposed in the third area on the substrate, wherein the fourth metal component is connected to the second conductive portion.

In the display panel, the array substrate comprises a display area and a non-display area, wherein the non-display area comprises a gate driver circuit area, and the gate driver circuit area comprises a first trace and a second trace; wherein the first area and the second area of the substrate are located corresponding to the display area of the array substrate; the third area of the substrate is located corresponding to the gate driver circuit area of the non-display area of the array substrate; and the second metal component is defined as the first trace of the gate driver circuit area, and the fourth metal component is defined as the second trace of the gate driver circuit area.

In the display panel, the first metal component is defined as a gate electrode and a scan line.

In the display panel, the third metal component is defined as a source electrode and a drain electrode.

In the display panel, the array substrate further comprises a protection layer, and the protection layer covers the electrically conductive layer and the second metal layer.

In the display panel, the array substrate further comprises a semiconductor layer disposed corresponding to the first area of the substrate and located between the first insulating layer and the electrically conductor layer.

In the display panel, the electrically conductive layer is made of indium tin oxide.

In the display panel, the display panel further comprises a color filter substrate disposed opposite to the array substrate, wherein the array substrate has an edge flush with an edge of the color filter substrate, and a side bonding area is defined between the edges of the array substrate and the color filter substrate for achieving a narrow bezel design for the display panel.

In the display panel, the side bonding area comprises an electrically conductive film comprising a side attached to the edges of the color filter substrate and the array substrate, wherein the array substrate comprises a bonding terminal, and the side of the electrically conductive film is electrically connected to the bonding terminal; a chip-on film attached to a side of the electrically conductive film away from the color filter substrate and the array substrate; and an electrically conductive adhesive disposed between the chip-on film and the electrically conductive film for electrically bonding the chip-on film and the electrically conductive film.

In the display panel, the electrica v conductive adhesive is an anisotropic conductive adhesive.

In the display panel, the electrically conductive film is made of silver.

In comparison with the prior art, embodiments of the present application provide an array substrate and a method of manufacturing the same, and the display panel. The array substrate includes a substrate including a first area, a second area, and a third area, wherein the second area is disposed between the first area and the third area; a first metal layer including a first metal component disposed in the first area on the substrate and a second metal component disposed in the third area on the substrate; a first insulating layer covering the first metal layer and the substrate, wherein the first insulating layer is provided with a through hole corresponding to a position of the third area; an electrically conductive layer disposed on a side of the first insulating layer away from the first metal layer and including a plurality of first conductive portions disposed in the first area and the second area, a second conductive portion disposed in the third area, and at least part of the second conductive portion connected to the second metal component through the through hole; and a second metal layer including a third metal component disposed in the first area on the substrate and a fourth metal component disposed in the third area on the substrate, wherein the fourth metal component is connected to the second conductive portion, so that a length of the second conductive portion used to be in contact with the second metal component and the fourth metal component is reduced, thereby reducing a contact resistance between the first metal layer and the second metal layer. In the process of manufacturing the array substrate, both the electrically conductive layer and the second metal layer can be patterned concurrently by the same halftone mask, not only saving two masks and two exposure and development processes, but also simplifying the process of manufacturing the array substrate. In this manner, the array substrate and the method of manufacturing the same, and the display panel provided by the embodiments of the present application can overcome the problem that gradient lines are likely to occur in a display panel, as well as improving display quality of the display panel.

### BRIEF DESCRIPTION OF DRAWINGS

FIG. 1 is a schematic structural view of gate driver on array circuitry of a conventional display panel.

FIG. 2A is a schematic structural view of an. array substrate of an embodiment of the present application.

FIG. 2B is a top plan view of the array substrate of FIG. 2A.

FIG. 2C is an enlarged view of an I portion shown in FIG. 2B.

FIG. 2D is a schematic structural view of a display area of an array substrate in accordance with an embodiment of the present application.

FIG. 3 is a flowchart of manufacturing an array substrate in accordance with an embodiment of the present application.

FIGS. 4A to 4J are schematic views showing processes of the flowchart of manufacturing the array substrate in FIG. 3.

FIG. 5 is a schematic structural view of a display panel in accordance with an embodiment of the present application.

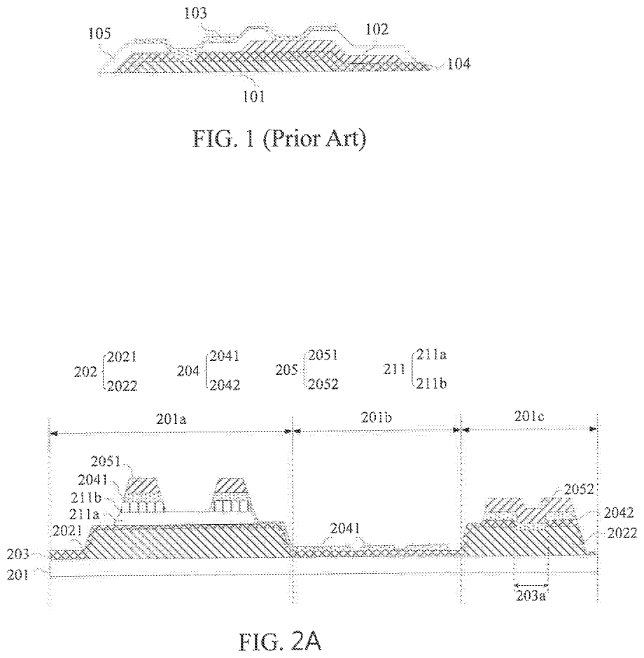

### DESCRIPTION OF PREFERRED EMBODIMENTS

In order to make the purpose, technical solution, and effect of the present application clearer and more definite, the present application is further described in detail below with reference to the accompanying drawings and examples. It should be understood that the specific embodiments described herein are only used to explain the application, and. are not used to limit the application.

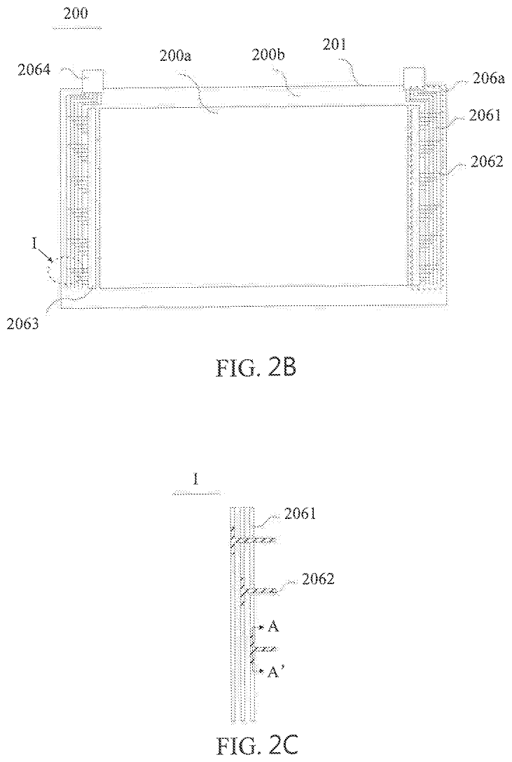

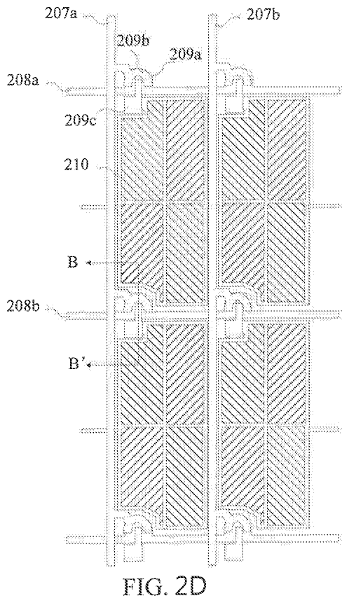

Specifically, please refer to FIG. 2A showing a schematic structural view of an array substrate of an embodiment of the present application. The array substrate includes a substrate 201 including a first area 201a, a second area 201b, and a third area 201c, wherein the second area 201b is disposed between the first area 201a and the third area 201c.

A first metal layer 202 includes a first metal component 2021 disposed in the first area 201a on the substrate 201 and a second metal component 2022 disposed in the third area 201c on the substrate 201.

A first insulating layer 203 covers the first metal layer 202 and the substrate 201, wherein the first insulating layer 203 is provided with a through hole 203a corresponding to a position of the third area 201c.

An electrically conductive layer 204 is disposed on a side of the first insulating layer 203 away from the first metal layer 202 and includes a plurality of first conductive portions 2041 disposed in the first area 201a and the second area 201b, a second conductive portion 2042 disposed in the third area 201c, and at least part of the second conductive portion 2042 connected to the second metal component 2022 through the through hole 203a.

A second metal layer 205 includes a third metal component 2051 disposed in the first area 201a on the substrate 201 and a fourth metal component 2052 disposed in the third area 201e on the substrate 201, wherein the fourth metal component 2052 is connected to the second conductive portion 2042 to reduce a contact resistance between first metal layer 202 and the second metal layer 205.

The array substrate further includes a semiconductor layer 211 disposed corresponding to the first area 201a of the substrate 201 and located between the first insulating layer 203 and the electrically conductor layer 204. The semiconductor layer 211 includes a source layer 211a and an ohmic contact layer 211b.

Please refer to FIG. 2B showing a top plan view of the array substrate of FIG. 2A.The array substrate 200 includes a display area 200a and a non-display area 200b, wherein the non-display area 200b includes a gate driver circuit area 206a, and the gate driver circuit area 206a includes a first trace 2061 and a second trace 2062.

Please continue referring to FIGS. 2A and 2B. The first area 201a and the second area 201b of the substrate 201 are located corresponding to the display area 200a of the array substrate 200.

The third area 201c of the substrate 201 is located corresponding to the gate driver circuit area 206a of the non-display area 200b of the array substrate 200.

The second metal component 2022 is defined as the first trace 2061 of the gate driver circuit area 206a, and the fourth metal component 2052 is defined as the second trace 2062 of the gate driver circuit area 206a.

The first trace 2061 is configured to be connected to a chip-on film 2064 or a printed circuit board, and transmits a signal through the chip-on film 2064 or the printed circuit board to a gate driver circuit 2063 over the second trace 2062, thereby to control a gate electrode.

Please refer to FIG. 2C which is an enlarged view of an I portion shown in FIG. 2B, wherein a schematic structural view of the third area 201c shown in FIG. 2A is a cross-sectional view taken along line A-A′ of FIG. 2C.

Please refer to FIG. 2D showing a schematic structural view of a display area of an array substrate in accordance with an embodiment of the present application. The array substrate includes a plurality of data lines 207a, 207b and a plurality of scan lines 208a, 208b. Adjacent two of the scan lines 208a, 208b and adjacent two of the data lines 207a, 207b cooperatively form a pixel area. A thin-film transistor and a pixel electrode 210 corresponding to the thin-film transistor are disposed above each pixel area. A description will be given by taking a plurality of the thin-film transistors under control of the scan lines 208a as an example. Each of the thin-film transistors has a gate electrode 209a, a source electrode 209b, and a drain electrode 209c. The gate electrode 209a of the thin-film transistor is electrically connected to one of the scan lines 208a, the source electrode 209b of the thin-film transistor is electrically connected to one of the data lines 207a, and the drain electrode 209c of the thin-film transistor is electrically connected to a corresponding one of the pixel electrodes 210. The first metal component 2021 is defined as the gate electrode 209a and the scan line 208a, The third metal component 2051 is defined as the source electrode 209b and the drain electrode 209c. A schematic structural view of the first area 200a and the second area 200b shown in FIG. 2A is a cross-sectional view taken along line B-B′ of FIG. 2D.

In certain embodiments, the array substrate 200 further includes a protection layer (not shown), and the protection layer covers the electrically conductive layer 204 and the second metal layer 205 to protect the electrically conductive layer 204 and the second metal layer 205 from corrosion.

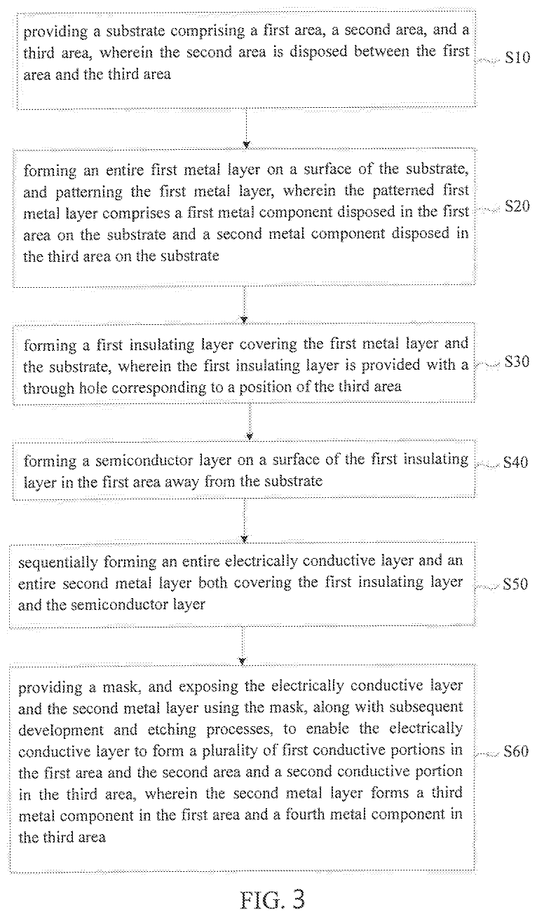

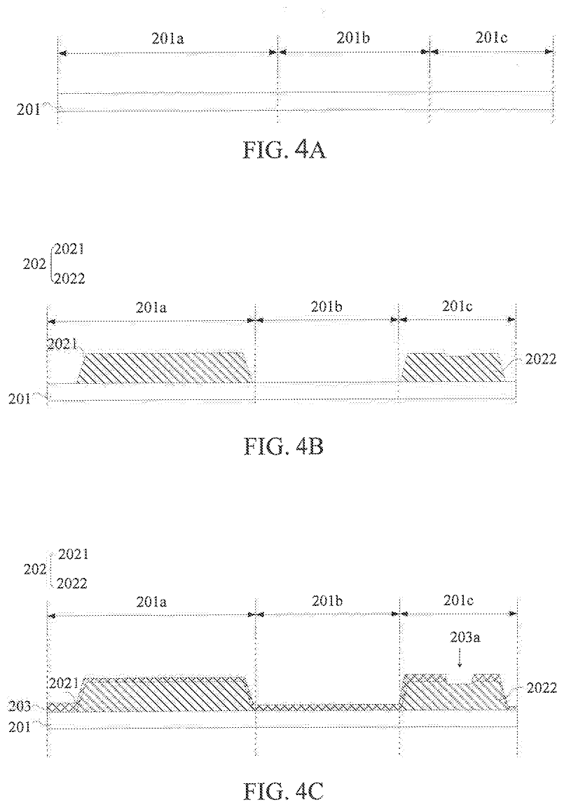

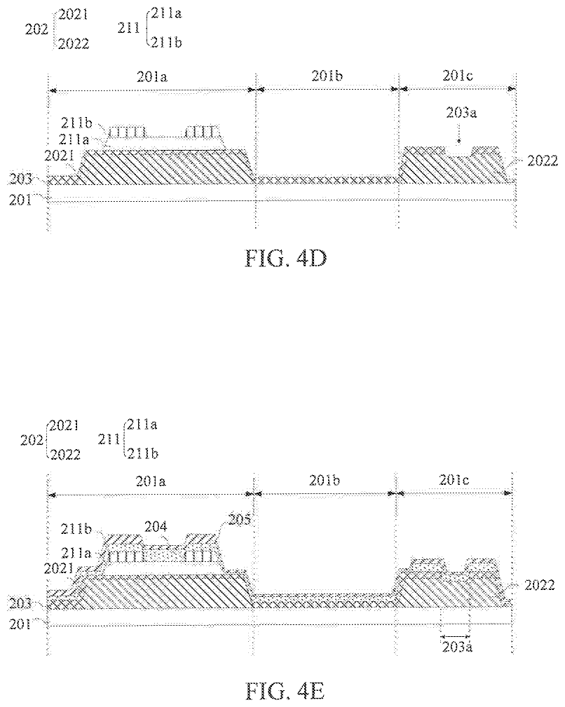

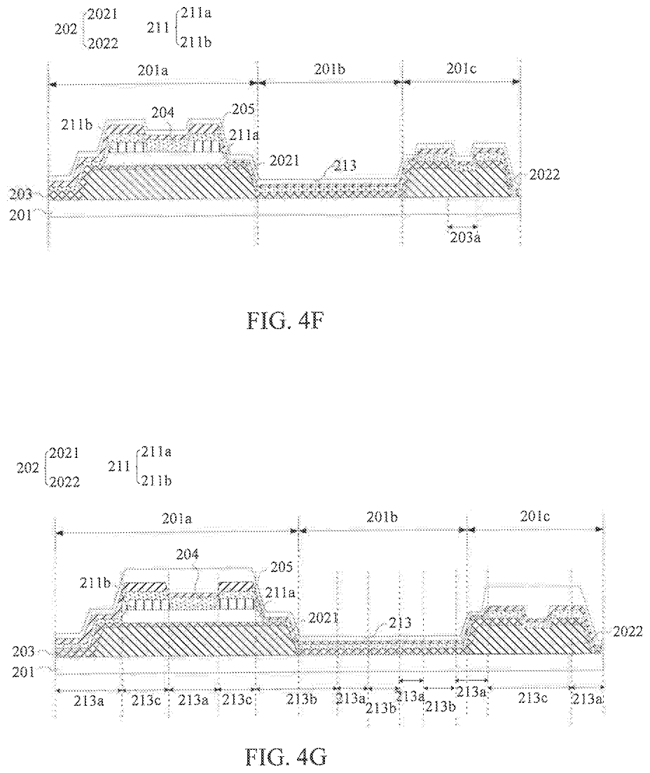

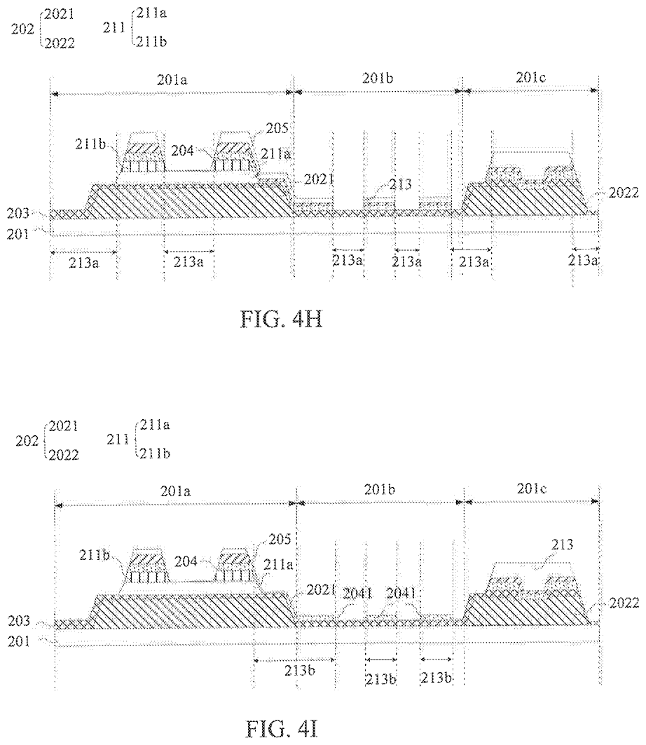

Please refer to FIG. 3 showing a flowchart of manufacturing an array substrate in accordance with an embodiment of the present application. FIGS. 4A to 4J are schematic views showing processes of the flowchart of manufacturing the array substrate in FIG. 3. The present application further provides a method of manufacturing an array substrate, The method includes following steps:

S10: providing a substrate 201 including a first area 201a, a second area 201b, and a third area 201c, wherein the second area 201b is disposed between the first area 201a and the third area 201c as shown in FIG. 4A.

S20: forming an entire first metal layer on a surface of the substrate 201, and patterning the first metal layer, wherein the patterned first metal layer 202 includes a first metal component 2021 disposed in the first area 201a on the substrate 201 and a second metal component 2022 disposed in the third area 201c on the substrate 201 as shown in FIG. 4B.

S30: forming a first insulating layer 203 covering the first metal layer 202 and the substrate 201, wherein the first insulating layer 203 is provided with a through hole 203a corresponding to a position of the third area 201c as shown in FIG. 4C.

S40: forming a semiconductor layer 211 on a surface of the first insulating layer 203 in the first area 201a away from the substrate 201, wherein the semiconductor layer 211 includes a source layer 211a and an ohmic contact layer 211b.

S50: sequentially forming an entire electrically conductive layer 204 and an entire second metal layer 205 both covering the first insulating layer 203 and the semiconductor layer 211 as shown in FIG. 4E.

S60: providing a mask, and exposing the electrically conductive layer 204 and the second metal layer 205 using the mask, along with subsequent development and etching processes, to enable the electrically conductive layer 204 to form a plurality of first conductive portions 2041 in the first area 201b and the second area 201c and a second conductive portion 2042 in the third area 201c, wherein the second metal layer 205 forms a third metal component 2051 in the first area 201a, and a fourth metal component 2052 in the third area 201c, as shown in FIG. 4J.

The mask includes a full exposure area, a half exposure area, and a reserved area. Step S60 further includes steps as follows:

S601: preparing a photoresist layer 213 on a surface of the second metal layer 205, as shown in FIG. 4F.

S602: exposing the photoresist layer 213 using the mask, wherein a first photoresist area 213a is formed on the photoresist layer 213 corresponding to the full exposure area of the mask, a second photoresist area 213b is formed on the photoresist layer 213 corresponding to the half exposure area of the mask, and a third photoresist area 213c is formed on the photoresist layer 213 corresponding to the reserved area of the mask, as shown in FIG. 4G.

S603: removing the photoresist layer 213, the second metal layer 205, and the electrically conductive layer 204 in the first photoresist area 213a, so that the semiconductor layer 211 is exposed to the first area 201a of the substrate 201, and exposing part of the first insulating layer 203 to the second area 201b and the third area 201c of the substrate 201, so that the electrically conductive layer 204 is patterned.

S604: removing the photoresist layer 213 and the second metal layer 205 in the second photoresist area 213b, so that the electrically conductive layer 204 is exposed to the first area 201a and the second area 201b of the substrate 201, and the plurality of first conductive portions 2041 are formed, as shown in FIG. 4I.

S605: removing the photoresist layer 213 in the third photoresist area 213c, so that the second metal layer 205 is exposed to the first area 201a of the substrate 201 and the third metal component 2051 is formed, and exposing the second metal layer 205 to the third area 201c of the substrate 201, so that the fourth metal component 2052 is formed, as shown in FIG. 4J.

The mask is a halftone mask, and the electrically conductive layer is made of indium tin oxide.

In step S603, step S604, and step S605, the photoresist layer 213 is removed through a photoresist asking and drying process, the second metal layer 205 corresponding to the first photoresist area 213a and the second photoresist area 213b is removed by a metal etching solution, and the electrically conductive layer 204 corresponding to the first photoresist area 213a is removed using indium tin oxide etching solution.

Based on the method of manufacturing the array substrate provided in the embodiments of the present application, a halftone mask is used for exposure of the electrically conductive layer 204 and the second metal layer 205, the full exposure area of the mask is used for formation of the first photoresist area 213a, the half exposure area of the mask is used for formation of the second photoresist area 213b, and the reserved area of the mask is used for formation of the third photoresist area 213c. The first photoresist area 213a, the second photoresist area 213b, and the third photoresist area 213c are etched, respectively. A gate electrode, a source electrode, and a drain electrode are formed on the substrate 201 corresponding to the first area 201. A pixel electrode is formed on the substrate 201 corresponding to the second area 201b. A first trace 2061 and a second trace 2062 are formed on the substrate 201 corresponding to the third area 201c. In this manner, two masks and two exposure and development processes are saved, the process of manufacturing the array substrate is simplified, and a contact resistance between the first trace 2061 and the second trace 2062 is also reduced.

In the method of manufacturing the array substrate, after step S60, the method further includes the following step: S70: fabricating a protection layer for covering the electrically conductive layer 204 and the second metal layer 205 to protect the electrically conductive layer 204 from corrosion.

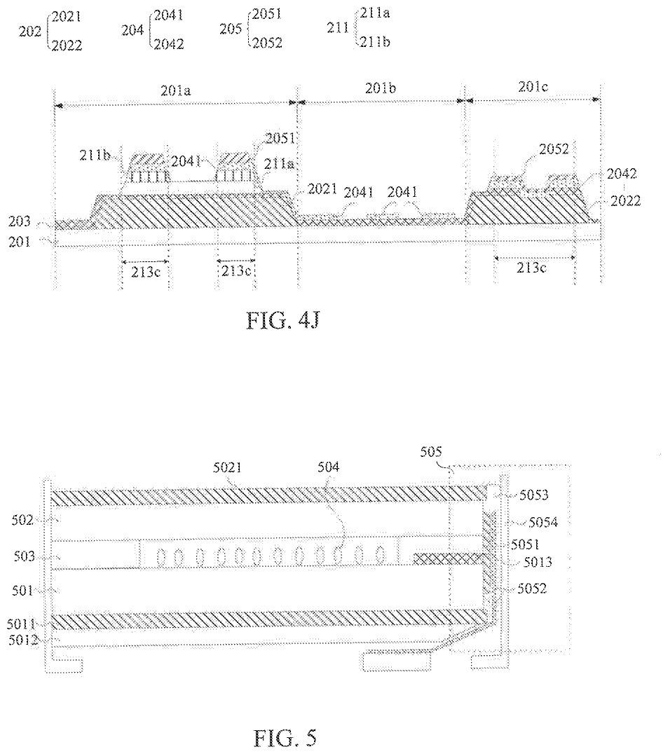

Please refer to FIG. 5 showing a schematic structural view of a display panel in accordance with an embodiment of the present application. One embodiment of the present application further provides a display panel. The display panel includes an array substrate 501.

The display panel further includes a color filter substrate 502 disposed opposite to the array substrate 501. A polarizer 5011 and a backlight source 5012 are disposed on a side of the array substrate 501 away from the color filter substrate 502. A polarizer 5021 is disposed on a side of the color filter substrate 502 away from the array substrate 501. A sealant 503 and liquid crystal molecules 504 are disposed between the array substrate 501 and the color filter substrate 502.

The array substrate 501 has an edge flush with an edge of the color substrate 502, and a side bonding area 505 is defined between the edges of the array substrate 501 and the color filter substrate 502. The side bonding area 505 includes following components.

An electrically conductive film 5051 having a side attached to the edges of the color filter substrate 502 and the array substrate 501, wherein the array substrate 501 includes a bonding terminal 5013, and the side of the electrically conductive film 5051 is electrically connected to the bonding terminal 50113.

A chip-on film 5052 is attached to a side of the electrically conductive film 5051 away from the color filter substrate 502 and the array substrate 501.

An electrically conductive adhesive 5053 is disposed between the chip-on film 5052 and the electrically conductive film 5051 for electrically bonding the chip-on film 5052 and the electrically conductive film 5051. The electrically conductive adhesive 5053 is further in contact with the sealant 5054 for fixing the color filter substrate 502 and the array substrate 501. The electrically conductive adhesive 5053 is an anisotropic conductive adhesive. The electrically conductive film 5051 is made of silver.

Because the first metal layer and the second metal layer of the array substrate 501 are electrically connected to each other directly through the electrically conductive layer, not only a contact resistance can be reduced, but also a contact area of a side bonding area can be increased. As a result, a problem of abnormal display caused by gradient lines occurring when the display panel is displaying images can be prevented from arising in the display panel, and therefore is also beneficial for narrow bezel design.

Embodiments of the present application provide an array substrate and a method of manufacturing the same, and the display panel. The array substrate 200 includes a substrate 201 including a first area 201a, a second area 201b, and a third area 201c, wherein the second area 201b is disposed between the first area 201a and the third area 201c; a first metal layer 202 including a first metal component 2021 disposed in the first area 201c on the substrate 202 and a second metal component 2022 disposed in the third area 201c on the substrate 201; a first insulating layer 203 covering the first metal layer 202 and the substrate 201, wherein the first insulating layer 203 is provided with a through hole 203a corresponding to a position of the third area 201c; an electrically conductive layer 204 disposed on a side of the first insulating layer 203 away from the :first metal layer 202 and including a plurality of first conductive portions 2041 disposed in the first area 201a and the second area 201b, a second conductive portion 2042 disposed in the third area 201c, and at least part of the second conductive portion 2042 connected to the second metal component 2022 through the through hole 203a; and a second metal layer 205 including a third metal component 2051 disposed in the first area 201a on the substrate 201 and a fourth metal component 2052 disposed in the third area 201c on the substrate 201, wherein the fourth metal component 2052 is connected to the second conductive portion 2042, so that a length of the second conductive portion 2042 used to be in contact with the second metal component 2022 and the fourth metal component 2052 is reduced, thereby reducing a contact resistance between the first metal layer 202 and the second metal layer 205. In the process of manufacturing the array substrate, both the electrically conductive layer 204 and the second metal layer 205 can be patterned concurrently by the same halftone mask, not only saving two masks and two exposure and development processes, but also simplifying the process of manufacturing the array substrate. In this manner, the array substrate and the method of manufacturing the same, and the display panel provided by the embodiments of the present application can overcome the problem that gradient lines are likely to occur in a display panel, as well as improving display quality of the display panel.

In the above embodiments, each embodiment as described has its own emphasis. For a part that is not described in detail in one of the embodiments, reference may be made to related descriptions in other embodiments.

The array substrate and the manufacturing method thereof, and the display panel provided in the embodiments of the present invention are described in detail above. Specific examples are used herein to explain the principle and implementation of this application. The descriptions of the above embodiments are only used to help understand the technical solution of this application and its core ideas. Those skilled in the art should understand that they can still modify the technical solutions described in the foregoing embodiments, or replace some of the technical features equivalent. These modifications or replacements do not make the essence of the corresponding technical solutions outside the scope of the technical solutions of the embodiments of the present application.

What is claimed is:

1. An array substrate, comprising:
a substrate comprising a first area, a second area, and a third area, wherein the second area is disposed between the first area and the third area;
a first metal layer comprising a first metal component disposed in the first area on the substrate and a. second metal component disposed in the third area on the substrate;
a first insulating layer covering the first metal layer and the substrate, wherein the first insulating layer is provided with a through hole corresponding to a position of the third area;
an electrically conductive layer disposed on a side of the first insulating layer away from the first metal layer and comprising a plurality of first conductive portions disposed in the first area and the second area, a second conductive portion disposed in the third area, and at least part of the second conductive portion connected to the second metal component through the through hole; and
a second metal layer comprising a third metal component disposed in the first area on the substrate and a fourth metal component disposed in the third area on the substrate, wherein the fourth metal component is connected to the second conductive portion.

2. The array substrate of claim 1, further comprising a display area and a non-display area, wherein the non-display area comprises a gate driver circuit area, and the gate driver circuit area comprises a first trace and a second trace;
wherein the first area and the second area of the substrate are located corresponding to the display area of the array substrate;
the third area of the substrate is located corresponding to the gate driver circuit area of the non-display area of the array substrate; and
the second metal component is defined as the first trace of the gate driver circuit area, and the :fourth metal component is defined as the second trace of the gate driver circuit area.

3. The array substrate of claim 1, wherein the first metal component is defined as a gate electrode and a scan line.

4. The array substrate of claim 1, wherein the third metal component is defined as a source electrode and a drain electrode.

5. The array substrate of claim 1, further comprising a protection layer, and the protection layer covers the electrically conductive layer and the second metal layer.

6. The array substrate of claim 1, further comprising a semiconductor layer disposed corresponding to the first area of the substrate and located between the first insulating layer and the electrically conductor layer.

7. A method of manufacturing an array substrate, comprising the following steps:
S10: providing a substrate comprising a first area, a second area, and a third area, wherein the second area is disposed between the first area and the third area;
S20: forming an entire first metal layer on a surface of the substrate, and patterning the first metal layer, wherein the patterned first metal layer comprises a first metal component disposed in the first area on the substrate and a second metal component disposed in the third area on the substrate;
S30: forming a first insulating layer covering the first metal layer and the substrate, wherein the first insulating layer is provided with a through hole corresponding to a position of the third area;
S40: forming a semiconductor layer on a surface of the first insulating layer in the first area away from the substrate;
S50: sequentially forming an entire electrically conductive layer and an entire second metal layer both covering the first insulating layer and the semiconductor layer; and
S60: providing a mask, and exposing the electrically conductive layer and the second metal layer using the mask, along with subsequent development and etching processes, to enable the electrically conductive layer to form a plurality of first conductive portions in the first area and the second area and a second conductive portion in the third area, wherein the second metal layer forms a third metal component in the first area and a fourth metal component in the third area.

8. The manufacturing method of claim 7, wherein the mask comprises a full exposure area, a half exposure area, and a reserved area, wherein the step S60 further comprises:
S601: preparing a photoresist layer on a surface of the second metal layer;
S602: exposing the photoresist layer using the mask, wherein a first photoresist area is formed on the photoresist layer corresponding to the full exposure area of the mask, a second photoresist area is formed on the photoresist layer corresponding to the half exposure area of the mask, and a third photoresist area is formed on the photoresist layer corresponding to the reserved area of the mask;
S603: removing the photoresist layer, the second metal layer, and the electrically conductive layer in the first photoresist area, so that the semiconductor layer is exposed to the first area of the substrate, and exposing part of the first insulating layer to the second area and the third area of the substrate, so that the electrically conductive layer is patterned;
S604: removing the photoresist layer and the second metal layer in the second photoresist area, so that the electrically conductive layer is exposed to the first area and the second area of the substrate, and the plurality of first conductive portions are formed; and
S605: removing the photoresist layer in the third photoresist area, so that the second metal layer is exposed to the first area of the substrate and the third metal component is formed, and exposing the second metal layer to the third area of the substrate, so that the fourth metal component is formed.

9. The manufacturing method of claim 7, wherein after the step S60, the manufacturing method further comprises S70: fabricating a protection layer for covering the electrically conductive layer and the second metal layer.

10. A display panel, comprising the array substrate of claim 1, wherein the array substrate comprises:
a substrate comprising a first area, a second area, and a third area, wherein the second area is disposed between the first area and the third area;
a first metal layer comprising a first metal component disposed in the first area on the substrate and a second metal component disposed in the third area on the substrate;
a first insulating layer covering the first metal layer and the substrate, wherein the first insulating layer is provided with a through hole corresponding to a position of the third area;
an electrically conductive layer disposed on a side of the first insulating layer away from the first metal layer and comprising a plurality of first conductive portions disposed in the first area and the second area, a second conductive portion disposed in the third area, and at least part of the second conductive portion connected to the second metal component through the through hole; and
a second metal layer comprising a third metal component disposed in the first area on the substrate and a fourth metal component disposed in the third area on the substrate, wherein the fourth metal component is connected to the second conductive portion.

11. The display panel of claim 10, wherein the array substrate comprises a display area and a non-display area, wherein the non-display area comprises a gate driver circuit area, and the gate driver circuit area comprises a first trace and a second trace;
wherein the first area and the second area of the substrate are located corresponding to the display area of the array substrate;
the third area of the substrate is located corresponding to the gate driver circuit area of the non-display area of the array substrate; and
the second metal component is defined as the first trace of the gate driver circuit area, and the fourth metal component is defined as the second trace of the gate driver circuit area. The display panel of claim 10, wherein the first metal component is defined as a gate electrode and a scan line.

13. The display panel of claim 10, wherein the third metal component is defined as a source electrode and a drain electrode.

14. The display panel of claim 10, further comprising a protection layer, and the protection layer covers the electrically conductive layer and the second metal layer.

15. The display panel of claim 10, further comprising a semiconductor layer disposed corresponding to the first area of the substrate and located between the first insulating layer and the electrically conductor layer.

16. The display panel of claim 10, wherein the electrically conductive layer is made of indium tin oxide.

17. The display panel of claim 10, further comprising a color filter substrate disposed opposite to the array substrate, wherein the array^{,} substrate has an edge flush with an edge of the color filter substrate, and a side bonding area is defined between the edges of the array substrate and the color filter substrate for achieving a narrow bezel design for the display panel.

18. The display panel of claim 17, wherein the side bonding area comprises:
an electrically conductive film comprising a side attached to the edges of the color filter substrate and the array substrate, wherein the array substrate comprises a bonding terminal, and the side of the electrically conductive film is electrically connected to the bonding terminal;
a chip-on film attached to a side of the electrically conductive film away from the color filter substrate and the array substrate; and
an electrically conductive adhesive disposed between the chip-on film and the electrically conductive film for electrically bonding the chip-on film and the electrically conductive film.

19. The display panel of claim 18, wherein the electrically conductive adhesive is an anisotropic conductive adhesive.

20. The display panel of claim 18, wherein the electrically conductive film is made of silver
